(19) United States
(12) Patent Application Publication
(10) Pub. No.: US 2010/0173100 A1
(43) Pub. Date: Jul. 8, 2010

(54) METHOD FOR THE SYNTHESIS OF PRODUCT MOLECULES

(75) Inventors: Horst Weiss, Neuhofen (DE); Gustav Gerber, Kirchzarten (DE); Patrick Henning Nürnberger, Wurzburg (DE); Daniel Stephan Wolpert, Bisingen (DE)

Correspondence Address: CONNOLLY BOVE LODGE & HUTZ, LLP, P O BOX 2207, WILMINGTON, DE, 19899, US

(73) Assignee: BASF, Ludwigshafen (DE)

(21) Appl. No.: 12/160,994

(22) PCT Filed: Jan. 15, 2007
(86) PCT No.: PCT/EP2007/050337

§ 371 Date: Jul. 15, 2008

(30) Foreign Application Priority Data
Jan. 16, 2006 (EP) 06100371.1

(51) Int. Cl. C23C 16/48

(52) U.S. Cl. 427/582

(57) ABSTRACT

The invention relates to a method for the synthesis of product molecules, wherein ultrashort laser pulses shaped with the aid of a pulse shaper are generated and a gas which contains educt molecules is fed onto a surface, on which the educt molecules are at least partially adsorbed, the shaped ultrashort laser pulses being directed onto the surface in order to control a reaction process for synthesis of the product molecules from educts adsorbed on the surface.

The invention relates to a method for the synthesis of product molecules, with which the process of chemical reactions can be controlled deliberately.

The deliberate control of chemical reactions at a molecular level is an old dream of chemistry. The conventional macroscopic control parameters of chemistry such as temperature, concentration or pressure do not allow direct access to the quantum-mechanical reaction process. During recent years many new discoveries have been made in the field of quantum control, in which specially configured light fields are employed with the aid of which particular reaction channels can be selected efficiently and selectively. One experimental technique is based on the manipulation of femtosecond laser pulses by means of a pulse shaper. This technique is described for example in the review article by T. Brixner, G. Gerber “Quantum Control of Gas-Phase and Liquid-Phase Femtochemistry”, CHEMPHYSCHEM 2003, 4, 418 to 438. The starting point is a laser pulse with a duration of a few femtoseconds (conventionally 10 to 150 fs), which can be generated by a commercial laser system. This laser pulse is converted into a “shaped” laser pulse by means of a so-called pulse shaper, in which case the shaping relates to the phases and/or amplitudes of the coherent spectral components which need no longer be uniform but can be modulated and thus adapted for the reaction process to be optimized.

Such methods have to date been successfully applied mainly for dissociative reactions in the gas phase. It is an object of the invention to avoid the disadvantages of the prior art and, in particular, to allow selective formation of molecular bonds with shaped ultrashort laser pulses.

This object is achieved according to the invention by a method for the synthesis of product molecules, wherein ultrashort laser pulses shaped with the aid of a pulse shaper are generated and a gas which contains educt molecules is fed onto a surface, on which the educt molecules are at least partially adsorbed, the shaped ultrashort laser pulses being directed onto the surface in order to control a reaction process for synthesis of the product molecules from educts adsorbed on the surface.

The product molecules are in this case molecules whose yield can be deliberately influenced by the shaped laser pulses. They result from chemical reactions of educts on the surface under the influence of the laser pulses.

Ultrashort laser pulses in the context of the method according to the invention are laser pulses whose duration (the shortest possible according to the time-bandwidth product) lies in the range from an attosecond to 1 nanosecond, preferably in the range from 1 femtosecond to 10 picoseconds, particularly preferably in the range from 5 to 200 femtoseconds. Such ultrashort laser pulses are provided in particular by commercial femtosecond lasers.

Synthesis in the context of the invention means the production of product molecules in which new molecular bonds occur, and in which the educt molecules or the educts are not merely decomposed into their constituents. Furthermore, the synthesis of product molecules in the method according to the invention preferably takes place through multi-molecular reactions, in particular through bimolecular reactions.

According to the invention a gas which contains the educt molecules is fed onto the surface, on which it is at least partially adsorbed. In order to control a reaction process for synthesis of the product molecules from educts adsorbed on the surface, the shaped ultrashort laser pulses are directed onto the surface. The educt adsorbed on the surface may in this case correspond to educt molecules from the gas fed onto the surface, or smaller (dissociative process) or larger (aggregation) molecules or atoms resulting therefrom.

The shaped ultrashort laser pulses are preferably shaped for the method according to the invention so that the reaction yield of the product molecules is maximized. The shaped ultrashort laser pulses may, however, also be shaped so that the reaction yield of a product other than the product molecules to be synthesized is minimized.

The method according to the invention for the synthesis of product molecules is preferably carried out by feeding a continuous mass flow rate of gas with the educt molecules onto the surface, and by directing shaped ultrashort laser pulses onto the surface with a particular repetition rate.

The surface is used to adsorb the educts in the present invention, and must therefore have an affinity with, the educt molecules in the gas. The surface should at least physisorb the educt molecules or educts, and optionally even chemisorb them. During physisorption, the adsorbed educt molecules remain in their original chemical state. During chemisorption, however, the adsorbates form a chemical bond with the surface. The adsorbate may in this case dissociate on the surface. Use of the surface offers the advantage, inter alia, that a relatively high density of the educt substances is achieved. This leads to a higher collision rate and higher yields. In the gas phase, the probability that a plurality of particles will meet would be much too low. The surface may furthermore act for example as a catalyst for the dissociation or aggregation of educt molecules, or the special nature of the (e.g. metallic) support is exploited as described for example in M. Bonn et al.,: “Phonon-Versus Electron-Mediated Desorption and Oxidation of CO on Ru(0001)”, SCIENCE 1999, 285, 1042 to 1045.

In the method according to the invention, the shaped ultrashort laser pulses interact with the surface and the adsorbed educts for synthesis of the product molecules. According to a preferred embodiment of the present invention, in addition to its function as a sorbent, the surface also fulfils the function of a catalyst which catalyzes the synthesis of product molecules.

According to a preferred embodiment of the present invention, the pulse shaper shapes spectral components of the laser pulses in respect of intensity (amplitude) and phase. The unshaped laser pulses, which are emitted for example by a commercial femtosecond laser and in which all spectral components occur at the same time, are in this case shaped by the pulse shaper into shaped laser pulses which can have variably adjusted components of the various spectral colours at different times. The pulse shaper may also vary the duration of a laser pulse, so long as its spectral width makes it possible to generate a laser pulse in the desired time range. The relative colour components (intensity) and their temporal arrangement (phase) in the shaped ultrashort laser pulse directly influence the yield during synthesis of the product molecules from educts adsorbed on the surface.

According to one embodiment of the present invention, the pulse shaper shapes spectral components of laser pulses in respect of polarization. This provides another parameter for optimization of the laser pulse shape, by which the yield of product molecules can be increased further. The pulse shaper in this case controls the polarization state of light on an ultrashort timescale. Such a polarization pulse shaper preferably manipulates the transient intensity, the instantaneous frequency, the degree of ellipticity and the orientation of the elliptical major axes in each individual ultrashort laser pulse.

A preferred embodiment of the method according to the invention consists in carrying out optimization of the shaped ultrashort laser pulses during the synthesis by using a detector to measure which products occur with which yields during synthesis of the product molecules, generating a modified pulse shape by means of a computer using an optimization algorithm and driving the pulse shaper so that the shaped ultrashort laser pulses are generated with the modified pulse shape. This has the advantage that no prior knowledge about the educt molecules/educts, the surface or the process of the chemical reaction is necessary for the optimization. The computer (for example a personal computer) undertakes the control of the pulse shaper and may, for example, optimize the reaction yield. The iterative improvement of the laser pulse shape takes place as follows. Ultrashort laser pulses are directed onto the surface in order to initiate a reaction for synthesis of the product molecules. A detector is used to measure which products are in this case generated with which yield. Any detector known to the person skilled in the art, which is suitable for detection of the products, may be used as a detector. The detector is preferably a detector which is based on at least one of the time-resolved detection methods selected from the group: time of flight mass spectroscopy, photoelectron spectroscopy, emission spectroscopy and two-dimensional spectroscopy and four-wave mixing.

The computer processes the information determined by the detector concerning the yields of the various products. Improved pulse shapes of the laser pulses are generated by the optimization algorithm, which are in turn generated by the pulse shaper and directed onto the surface for synthesis of the product molecules. This optimization method is repeated until the synthesis of product molecules is optimized, for example to a maximum of the desired product molecule yield (selectivity) relative to the yield of an undesired product, or to a minimum of a relative yield (selectivity) of such an undesired product.

An evolutionary algorithm is preferably used as the optimization algorithm in this case. This computer algorithm is a self-learning method, which is modelled on biological evolution. According to Darwin's “survival of the fittest” principle, laser pulses which fulfil the optimization criterion particularly well are selected and bred by combination with similarly successful phase settings. Some of the “progeny” generated by this are in turn more suitable than their “forebears” (they are assigned a higher “fitness”, and these are again selected for reproduction. Once this process of evolution has been performed for sufficiently many generations, a laser pulse which provides the optimal reaction result is finally obtained.

According to a preferred embodiment of the present invention, the laser pulses are shaped by a pulse shaper which is based on a computer-controlled technique, which comprises driving at least one device selected from the group: liquid-crystal display, acousto-optical modulator, acousto-optical filter, deformable mirror and micromirror arrangement. The shaping of a laser pulse by means of a pulse shaper in respect of spectral intensity and phase, as well as polarization, is conventionally based on splitting the laser pulse into its spectral components (for example by means of a grating or by means of prisms), generating a parallel ray bundle therefrom, inducing a time of flight difference for the spectral components by a device acting as a “phase shifter” and refocusing the ray bundle and (for example by another grating) superposing it to form a shaped laser pulse. At least one liquid-crystal display (LCD), acousto-optical modulator, deformable mirror or micromirror arrangement may for example be used as such a device acting as a “phase shifter”, or even an acousto-optical filter although splitting of the spectral components is not necessary for this.

The manipulation of the pulse shape by means of a liquid-crystal display is carried out by applying suitable electrical voltages to the individual LCD pixels, so that the refractive index can be selected in such a way that the various spectral components are time-delayed relative to one another during propagation through the LCD.

The acousto-optical filter is based on another method, in which the light does not first need to be split into its spectral components. Rather, the light and an acoustic wave propagate through a special birefringent crystal. Each spectral component can be diffracted by the acoustic grating at a particular position in the crystal, for example from an ordinary ray into an extraordinary ray. The resulting pulse therefore consists of the individual colour components which have been diffracted at different times, so that phase modulation is possible.

According to a preferred embodiment of the present invention, the gas containing the educt molecules is fed onto a surface which is a metallic surface or a metal oxide surface, and which preferably contains at least one element from subgroups IIIB to IIB (transition metals), particularly preferably from one of the groups VIIIB, IB and IIB of the periodic table. Preferred elements from groups VIIIB, IB and IIB of the periodic table are in this case Fe, Co, Ni, Cu, Zn, Ru, Rh, Pd, Ag, Cd, Os, Ir, Pt, Au and Hg. The metals may also be present as an alloy in the surface used for the method according to the invention or, according to a further embodiment, the gas containing the educt molecules is fed onto a surface which is a single-crystal surface of a transition metal, for example Pd (100), Pt (100) or Ag (111). According to a further preferred embodiment of the present invention, the surface is a surface of a technical catalyst, for example a technical catalyst which contains the said elements supported or unsupported, in pure form, as alloys or as oxides.

The gas which is fed onto the surface in the method according to the invention contains one or more types of educt molecules. For example, product molecules may be synthesized according to the invention by a polymerization reaction of just one type of educt molecules. It preferably contains a mixture of at least two types of educt molecules, in which case a ratio of mass flow rates of the at least two types of educt molecules may be regulated by a control device. Like the pulse shape of the shaped laser pulses, the ratio of the mass flow rates also has an influence on the yield of the product molecules when carrying out the method according to the invention. A control device may therefore regulate the mass flow rates of the at least two types of educt molecules so that a particular maximal yield of the product molecules is achieved.

A gas which contains at least one type of educt molecules selected from the following group is preferably fed onto the surface in the method according to the invention: acetone, acetylene, methanoic acid, ammonia, arsine, hydrogen cyanide, boron trichloride, boron trifluoride, bromoethene, bromomethane, hydrogen bromide, 1,3-butadiene, butane, 1-butene, 1-butyne, chlorine, chlorodifluoromethane, chloroethene, chloromethane, hydrogen chloride, cis-2-butene, deuterium, dichlorosilane, diethyl ether, difluoromethane, dimethylamine, dimethyl ether, 2,2-dimethylpropane, disilane, dinitrogen monoxide, nitrous oxide, ethane, ethene, ethylene oxide, fluoromethane, formaldehyde, hexafluoroethane, isobutane, isobutene, carbon dioxide, carbon monoxide, methane, methanol, methylamine, octafluorocyclobutane, octafluoropropane, phosphine, propane, propene, 1-propyne, propylene oxide, oxygen, sulfur dioxide, sulfur hexafluoride, hydrogen sulfide, silane, silicon tetrafluoride, nitrogen, nitrogen dioxide/dinitrogen tetroxide, nitrogen monoxide, nitrogen trifluoride, tetrafluoromethane, trans-2-butene, trifluoromethane, trimethylamine and hydrogen. The gas particularly preferably contains H₂ and CO as educt molecules. The method according to the invention may, for example, be used for the synthesis of formaldehyde or methanol.

According to one embodiment of the present invention, the gas containing the educt molecules is fed onto the surface in a vacuum chamber. A vacuum <10⁻³ mbar, in particular <10⁻⁴ mbar, is preferably set up in the vacuum chamber when the gas is delivered to the surface.

The present invention will be explained in more detail below with reference to the drawing, in which:

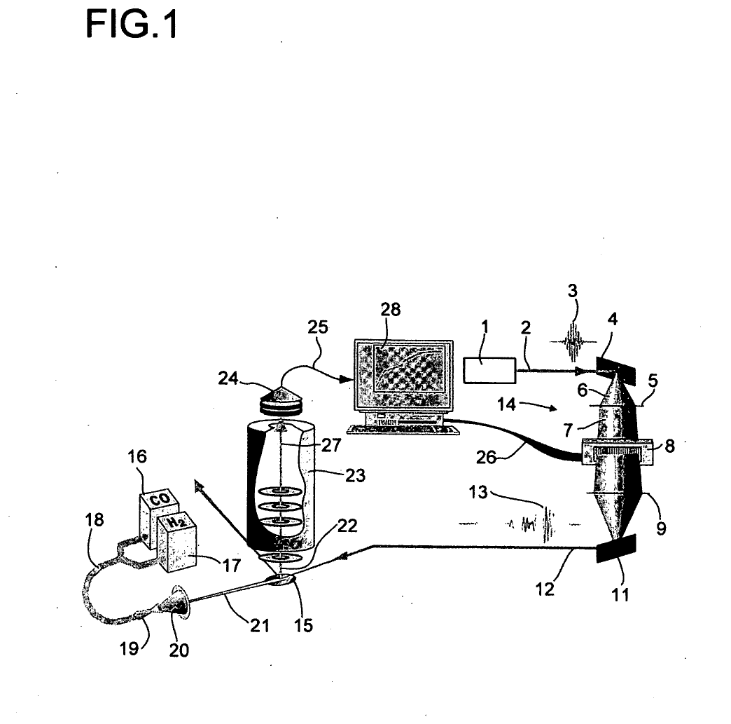

FIG. 1 schematically shows an arrangement for carrying out the method according to the invention for the synthesis of product molecules, and

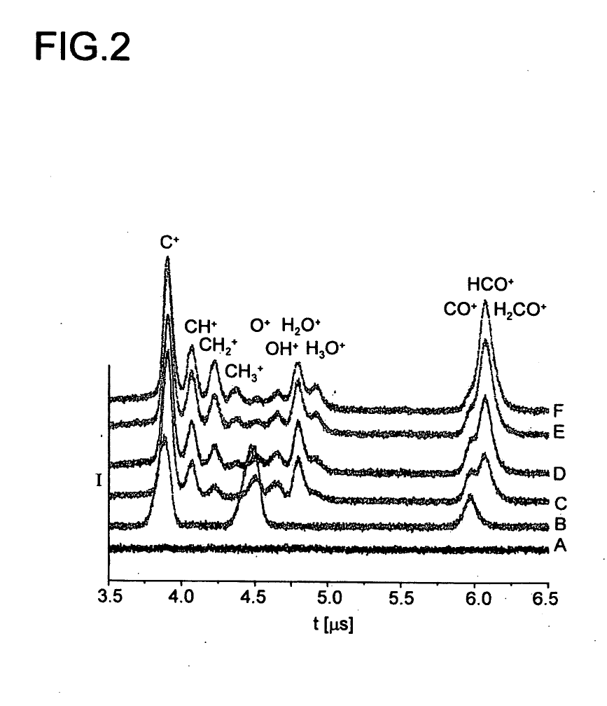

FIG. 2 shows mass spectra of Example 1 below, in which a gas containing CO and H₂ at different concentrations was fed onto a Pd (100) single-crystal surface and product molecules were synthesized by means of shaped ultrashort laser pulses.

FIG. 1 schematically shows an arrangement for carrying out the method according to the invention for the synthesis of product molecules from a gas containing CO and H₂ on a surface by means of shaped ultrashort laser pulses.

A laser 1 delivers laser pulses 2 whose spectral width makes it possible to generate laser pulses in the femtosecond range. The laser pulses 2 are optionally amplified (not shown) and, as unshaped laser pulses 3, strike a first grating 4 that resolves the unshaped laser pulses into their spectral components which strike a first lens 5 as divergent rays 6. The first lens 5 collimates the divergent rays 6 into a parallel ray bundle 7. A liquid-crystal display (LCD) 8 induces a time of flight difference of the various spectral components. A second lens 9 focuses the ray bundle 10 emerging from the liquid-crystal display 8, which is then superposed by a second grating 11 to form laser pulses 12. The pulse shaper of this arrangement consequently comprises the two gratings 4, 11, the two lenses 5, 9 and the liquid-crystal display 8. The ultrashort laser pulses 13 shaped in this way are directed onto a surface 15, which is optionally contained in a vacuum chamber (not shown).

The educt molecules CO and H₂ from a CO reservoir 16 and an H₂ reservoir 17 are mixed in a particular ratio of mass flow rates. The mixture 18 is fed through a nozzle 19 and a skimmer 20 onto the surface 15. Educts from the gas 21 striking the surface 15 are adsorbed on the surface 15. The shaped laser pulse 13 striking the surface 15 delivers the energy for synthesizing product molecules 22 from the adsorbed educts. The ionized product molecules 22 are accelerated in a time of flight spectrometer 23. In a detector 24, the ions 27 generate a signal based on times of flight through the time of flight spectrometer 23, which depend on their mass. These measured signals 25 are sent to a computer 28 which generates a modified pulse shape by means of an optimization algorithm in order to optimize the pulse shape of the shaped laser pulses 13. Via the connection 26, the computer 28 then drives the liquid-crystal display 8 so that the pulse shaper 14 shapes laser pulses with the modified pulse shape which has been generated, which are used for the synthesis of product molecules on the surface 15.

### EXAMPLE 1

A layout as represented in FIG. 1 was used. Laser pulses were amplified by means of a titanium-sapphire regenerative femtosecond amplifier, the amplified unshaped laser pulses having a pulse duration of 80 fs, pulse energies of up to 1 mJ with a central wavelength of 800 nm and a repetition rate of 1 kHz. An LCD pulse shaper with 128 pixels was used in order to modify the spectral phase of the laser pulses while their spectrum remained unaltered. The laser beam (shaped laser pulses) was focused by a lens with a focal length of 40 cm onto a Pd (100) single-crystal surface (temperature of the crystal 290 K) at an angle of about 15° in a main vacuum chamber (pressure without gas stream about 10⁻⁶ mbar). The intensity of the laser beam was about 10⁻¹² W/cm². The beam was reflected by the surface and left the main vacuum chamber.

The two gases H₂ and CO were obtained respectively with a purity of at least 99.999% (from Messer-Griesheim, Germany) and at least 99.997% (from Tyczka, Germany). Two mass flow regulators (from Advanced Energy, Germany) dosed the gas quantities which were fed into the system via two gas lines. The two gas lines were brought together before a nozzle and the gas mixture was fed through the nozzle into a secondary vacuum chamber when it struck a skimmer, and was fed from there as a gas stream into the main vacuum chamber. The Pd (100) single crystal (diameter 10 mm, thickness 1 mm from Mateck, Germany) was aligned at an angle of about 5° to the molecular flow, so that the gas not just grazed but struck it.

A time of flight mass spectrometer was arranged perpendicularly to the gas flow and almost parallel to the surface normal, with an electrode system for accelerating ions which resulted when the laser beam interacted with the surface and the adsorbed educts.

First results of the method according to the invention are represented in FIG. 2. The intensity I of an ion signal measured by means of a detector at the end of the time of flight mass spectrometer is plotted on the ordinate, and the time of flight t in μs is plotted on the abscissa. The results of 6 measurements A to F are shown, in which the respective mass flow rates of the two CO and H₂ educt molecular flows were selected as follows:

| Measurement | Gas flow CO/sccm | Gas flow H₂/sccm |
|---|---|---|
| A | 0.0 | 4.0 |
| B | 4.0 | 0.0 |
| C | 4.0 | 4.0 |
| D | 4.0 | 6.0 |
| E | 4.0 | 8.0 |
| F | 4.0 | 10.0 |

where sccm stands for standard ccm/min.

Only H₂ and no CO was fed onto the surface in measurement A. No signals are to be seen in the time window represented, although three mass peaks were observed which could be assigned to H⁺, H₂⁺ and H₃⁺.

Only CO and no H₂ was fed onto the surface in measurement B. The three detected peaks lie at masses 12, 16 and 28 amu, which can be assigned to C⁺, O⁺ and CO⁺.

Both educt molecule types CO and H₂ were fed as a gas mixture to the surface for measurements C to F, and the ions C⁺, CH⁺, CH₂⁺, CH₃⁺, O⁺, OH⁺, H₂O⁺, H₃O⁺, CO⁺, HCO⁺ and H₂CO⁺ were detected at different intensities depending on the ratio of the mass flow rates. The water peak (H₂O⁺) increases for example with an increasing H₂ mass flow rate, the O⁺ peak becoming smaller. The yield of particular product molecule forms could be improved further (not shown) by optimizing the laser pulse shapes. The detection for example of CH₃⁺ shows that 3 particles must have come together and interacted with the surface and the laser pulse. Synthesis of product molecules was therefore successfully achieved by means of the method according to the invention.

### EXAMPLE 2

Optimization of the pulse shape of the shaped ultrashort laser pulses was carried out by means of an evolutionary algorithm. To this end a 1:1 mixture of the two gases CO and H₂ was fed onto a Pd surface. The intention was to study whether it is possible with the aid of the evolutionary algorithm to find a pulse shape which influences the formation of C—H bonds. The object set for the optimization experiment was to maximize the formation of CH⁺ in relation to C⁺. The evolutionary algorithm was used to find a pulse shape of the shaped laser pulses which achieved an increase in the relative yield by about 50% compared with an unshaped femtosecond laser pulse. The CH₂⁺/C⁺ ratio was also increased by about the same value. A very surprising effect was furthermore the conspicuous reduction of H₂O⁺ formation with the optimized shaped femtosecond laser pulse. By varying the laser intensity, conversely, it was not possible to achieve any reduction of the H₂O⁺ signal relative to the other peaks. It consequently follows from these experimental data that the optimally shaped ultrashort laser pulse which was determined causes an increase in the signal of products with C—H bonds, whereas the signal of H₂O⁺ is reduced. The yields of CO⁺, HCO⁺ and H₂CO⁺ relative to C⁺ were likewise increased.

### EXAMPLE 3

The H₂O⁺ yield was integrated into the fitness function used by the evolutionary algorithm under comparable conditions as in Example 2. The optimization experiment was carried out with the selected object of maximizing the CH⁺/H₂O⁺ ratio. Via optimizing the laser pulse shape by means of the evolutionary algorithm, it was possible to reduce the H₂O⁺ peak relative to the C⁺ peak by about 50%. Before the optimization, the H₂O⁺ peak was greater than the CH⁺ peak. This ratio could be reversed by the optimized laser pulse shape. The CO⁺ and HCO⁺ peak intensities were increased, whereas CH⁺ and CH₂⁺ were virtually unchanged relative to C⁺. In this experiment as well, no reduction of the H₂O⁺ signal relative to the other peaks could be achieved by an intensity change of an unshaped laser pulse.

The results described in these examples clearly show that an evolutionary algorithm can be used in order to optimize the pulse shape of shaped ultrashort laser pulses for controlling two competing reaction channels, in which molecular bonds are formed and not simply broken.

The catalytic synthesis of product molecules can consequently be controlled selectively by the method according to the invention.

### LIST OF REFERENCES

1 laser
2 laser pulses
3 unshaped laser pulses
4 first grating
5 first lens
6 divergent rays
7 parallel ray bundle
8 liquid-crystal display
9 second lens
10 ray bundle
11 second grating
12 laser pulses
13 shaped laser pulses
14 pulse shaper
15 surface
16 CO reservoir
17 H₂ reservoir
18 mixture
19 nozzle
20 skimmer
21 gas
22 product molecules
23 time of flight mass spectrometer
24 detector
25 signals
26 connection
27 ions
28 computer

1. A method for the synthesis of product molecules, wherein ultrashort laser pulses shaped with the aid of a pulse shaper are generated and a gas which contains educt molecules is fed onto a surface, on which the educt molecules are at least partially adsorbed, the shaped ultrashort laser pulses being directed onto the surface in order to control a reaction process for synthesis of the product molecules from educts adsorbed on the surface.

2. The method as claimed in claim 1, wherein the pulse shaper shapes spectral components of laser pulses in respect of intensity and phase.

3. The method as claimed in claim 1, wherein the pulse shaper shapes spectral components of laser pulses in respect of polarization.

4. The method as claimed in claim 1, wherein optimization of the shaped ultrashort laser pulses is carried out during the synthesis by using a detector to measure which products occur with which yields during synthesis of the product molecules, generating a modified pulse shape by means of a computer using an optimization algorithm and driving the pulse shaper so that the shaped ultrashort laser pulses are generated with the modified pulse shape.

5. The method as claimed in claim 1, wherein the laser pulses are shaped by a pulse shaper which is based on a computer-controlled technique, which comprises driving at least one device selected from the group: liquid-crystal display, acousto-optical modulator, acousto-optical filter, deformable mirror and micromirror arrangement.

6. The method as claimed in claim 1, wherein the gas is fed onto a surface which is a single-crystal surface of a transition metal.

7. The method as claimed in claim 1, wherein a gas which contains one or more types of educt molecules is fed onto the surface.

8. The method as claimed in claim 1, wherein a gas which contains a mixture of at least two types of educt molecules is fed onto the surface, the ratio of mass flow rates of the at least two types of educt molecules being regulated by a control device.

9. The method as claimed in claim 1, wherein a gas which contains at least one type of educt molecules selected from the following group is fed onto the surface: acetone, acetylene, methanoic acid, ammonia, arsine, hydrogen cyanide, boron trichloride, boron trifluoride, bromoethene, bromomethane, hydrogen bromide, 1,3-butadiene, butane, 1-butene, 1-butyne, chlorine, chlorodifluoromethane, chloroethene, chloromethane, hydrogen chloride, cis-2-butene, deuterium, dichlorosilane, diethyl ether, difluoromethane, dimethylamine, dimethyl ether, 2,2-dimethylpropane, disilane, dinitrogen monoxide, nitrous oxide, ethane, ethene, ethylene oxide, fluoromethane, formaldehyde, hexafluoroethane, isobutane, isobutene, carbon dioxide, carbon monoxide, methane, methanol, methylamine, octafluorocyclobutane, octafluoropropane, phosphine, propane, propene, 1-propyne, propylene oxide, oxygen, sulfur dioxide, sulfur hexafluoride, hydrogen sulfide, silane, silicon tetrafluoride, nitrogen, nitrogen dioxide/dinitrogen tetroxide, nitrogen monoxide, nitrogen trifluoride, tetrafluoromethane, trans-2-butene, trifluoromethane, trimethylamine and hydrogen.

10. The method as claimed in claim 1, wherein the gas is fed onto the surface in a vacuum chamber.

11. The method as claimed in claim 2, wherein the pulse shaper shapes spectral components of laser pulses in respect of polarization.

12. The method as claimed in claim 2, wherein optimization of the shaped ultrashort laser pulses is carried out during the synthesis by using a detector to measure which products occur with which yields during synthesis of the product molecules, generating a modified pulse shape by means of a computer using an optimization algorithm and driving the pulse shaper so that the shaped ultrashort laser pulses are generated with the modified pulse shape.

13. The method as claimed in claim 3, wherein optimization of the shaped ultrashort laser pulses is carried out during the synthesis by using a detector to measure which products occur with which yields during synthesis of the product molecules, generating a modified pulse shape by means of a computer using an optimization algorithm and driving the pulse shaper so that the shaped ultrashort laser pulses are generated with the modified pulse shape.

14. The method as claimed in claim 2, wherein the laser pulses are shaped by a pulse shaper which is based on a computer-controlled technique, which comprises driving at least one device selected from the group: liquid-crystal display, acousto-optical modulator, acousto-optical filter, deformable mirror and micromirror arrangement.

15. The method as claimed in claim 3, wherein the laser pulses are shaped by a pulse shaper which is based on a computer-controlled technique, which comprises driving at least one device selected from the group: liquid-crystal display, acousto-optical modulator, acousto-optical filter, deformable mirror and micromirror arrangement.

16. The method as claimed in claim 4, wherein the laser pulses are shaped by a pulse shaper which is based on a computer-controlled technique, which comprises driving at least one device selected from the group: liquid-crystal display, acousto-optical modulator, acousto-optical filter, deformable mirror and micromirror arrangement.

17. The method as claimed in claim 2, wherein the gas is fed onto a surface which is a single-crystal surface of a transition metal.

18. The method as claimed in claim 3, wherein the gas is fed onto a surface which is a single-crystal surface of a transition metal.

19. The method as claimed in claim 4, wherein the gas is fed onto a surface which is a single-crystal surface of a transition metal.

20. The method as claimed in claim 5, wherein the gas is fed onto a surface which is a single-crystal surface of a transition metal.
